(19) United States
(12) Patent Application Publication
(10) Pub. No.: US 2022/0102145 A1
(43) Pub. Date: Mar. 31, 2022

(54) METHOD FOR FORMING RECESS AND FILLING EPITAXIAL LAYER IN SITU

(71) Applicant: SHANGHAI HUALI INTEGRATED CIRCUIT CORPORATION, Shanghai (CN)

(72) Inventors: Yaozeng WANG, Shanghai (CN); Yincheng Zheng, Shanghai (CN); Wangxin Nie, Shanghai (CN); Huojin Tu, Shanghai (CN); Jueyang Liu, Shanghai (CN); Zhanyuan Hu, Shanghai (CN)

(21) Appl. No.: 17/158,901

(22) Filed: Jan. 26, 2021

(30) Foreign Application Priority Data
Sep. 30, 2020 (CN) 202011056640.6

(51) Int. Cl. H01L 21/04; H01L 21/8234

(52) U.S. Cl. CPC H01L 21/042; H01L 21/823412

(57) ABSTRACT

The present application discloses a method for forming a recess, which comprises the following steps: step 1: performing a dry etching process to a silicon substrate to form a U-shaped or ball-shaped recess; step 2: performing second etching to the recess by introducing HCl and GeH₄ reaction gases in an epitaxial process chamber to form diamond-shaped recess. The present application further discloses a method for forming a recess and filling the recess with an epitaxial layer in situ. The disclosed etching changes U-shaped or ball-shaped reaction recess diamond-shaped recess by including reaction gases in the epitaxial process chamber, which is conducive to realizing the in-situ epitaxial filling process. This method reduces steps in the process loop of forming embedded epitaxial layer, thus decreasing defects from the process.

### CROSS-REFERENCES TO RELATED APPLICATIONS

This application claims priority to Chinese patent application No. CN202011056640.6, filed on Sep. 30, 2020, and entitled “METHOD FOR FORMING RECESS AND FILLING EPITAXIAL LAYER IN SITU”, the disclosure of which is incorporated herein by reference in entirety.

### TECHNICAL FIELD

The present application relates to a method for manufacturing a semiconductor integrated circuit, and in particular, to a method for forming a recess. The present application further relates to a method for forming a recess and filling an epitaxial layer in situ.

### BACKGROUND

Gate structures at the semiconductor IC process node of 28 nm have included a high-K metal gate (HKMG) and a polysilicon silicon oxide (Poly-SiOₓ) gate, where a HKMG is composed of a gate dielectric layer having a high-dielectric-constant (K) material and a metal gate, and where a Poly-SiOₓ gate is composed of a gate dielectric layer of silicon oxide, and a polysilicon gate. In 28 nm HKMG and Poly-SiOₓ process applied to 28 nm note, an embedded silicon germanium (SiGe) epitaxial (EPI) layer is usually applied in source and drain regions to improve device performance. The embedded SiGe EPI layer consists of SiGe EPI formed in a recess structure. Since the shape of the recess may shorten the distance between the source region and the drain region in the channel, the threshold voltage (Vth) is decreased, on current (Ion) is increased and device performance is improved. In recesses adopted by the embedded SiGe EPI, sigma-shaped recesses have become the most commonly used option in the industry, and the sigma-shaped recesses are also known as diamond-shaped recesses.

A method for forming a diamond-shaped recess widely used in the industry includes firstly performing etching to form a U-shaped or ball-shaped recess by applying a dry etching process, wherein the cross section of the U-shaped recess has a U-shape and the cross section of the ball-shaped recess is a circle with an open top; then performing selective etching to the crystal surface by applying tetramethylammonium hydroxide (TMAH) wet etch to form a diamond-shaped recess. Referring to FIG. 1A-1D, which are structural views of the device following each step in an existing method for forming a recess and filling it with an epitaxial layer, i.e., an embedded EPI loop in the recess; the existing method for forming the recess and filling with the epitaxial layer, includes the following steps:

In step 1, referring to FIG. 1A, first etching is performed, the first etching forms a recess 105 in a selected region of a silicon substrate 101, and the first etching enables the recess 105 to be U-shaped or ball-shaped by adopting dry etching. FIG. 1A illustrates that the recess 105 is ball-shaped, that is, the cross section is circular; alternatively the recess 105 may be U-shaped.

Usually, a top surface of the silicon substrate 101 is a surface (100).

The selected region of the recess 105 is source and drain forming regions on the two sides of a gate structure.

The gate structure is a superposition layer of a gate dielectric layer and a metal gate, and the gate dielectric layer includes a high-dielectric-constant K layer, that is, the gate structure is namely HKMG; in step 1, a pseudo gate structure is formed on the top surface of the silicon substrate 101, the pseudo gate structure is formed in a region of the gate structure, and the pseudo gate structure is formed by superposing a pseudo gate dielectric layer (not shown here) and a pseudo polysilicon gate 102; the pseudo gate structure is replaced by the gate structure in a subsequent process.

From FIG. 1A, it can be seen that a hard mask layer 103 is further formed on the top of the pseudo polysilicon gate 102, and sidewalls 104 are formed on the side surfaces of the pseudo gate structure. The hard mask layer 103 is formed by superposing a nitride layer 103b on an oxide layer 103a. The sidewalls 104 are formed by superposing nitride layer sidewalls 104b on oxide layer sidewalls 104a.

Alternatively, the gate structure is a superposition layer of a gate dielectric layer and a polysilicon gate, and the gate dielectric layer is composed of silicon oxide; in this case, in step 1, the gate structure is formed on the top surface of the silicon substrate 101, that is, the pseudo gate structure is not formed, instead the gate structure is directly formed on the surface of the silicon substrate 101.

In step 2, referring to FIG. 1B, a second etching is performed to the recess 105 by applying a wet etching process. Wet etching solution 106 for the second etching is usually TMAH.

Referring to FIG. 1C, the second etching enables the recess 105 to be diamond-shaped due to different etching rates into the three silicon crystal directions.

Generally, in step 2, the wet etching rates to the surface (110), the surface (100) and the surface (111) of silicon crystal decrease sequentially. In FIG. 1B, straight arrows are used to show the etching directions of the surface (110) and the surface (100). The arrow corresponding to the etching direction of the surface (100) faces downward, and the arrow corresponding to the etching direction of the surface (110) faces to the left and the right sides. Thus, the TMAH wet etching solution realizes selective etching of the crystal surfaces of the silicon substrate 101 to form a diamond-shaped recess 105.

In step 3, thereafter, referring to FIG. 1D, an epitaxial growth process is performed to form an epitaxial layer 107 to completely fill the recess 105. Generally, the epitaxial layer 107 is a silicon germanium epitaxial layer. The epitaxial growth process needs to be performed in an epitaxial process chamber.

### BRIEF SUMMARY

The present application provides a method for forming a recess. The method includes etching to a U-shaped or ball-shaped recess in a gate structure by introducing reaction gases into an epitaxial process chamber to form a diamond-shaped recess, which is conducive to realizing the recess etching and epitaxial filling process in situ. The method for forming a recess and filling an epitaxial layer in situ reduces the process steps in the process loop of an embedded epitaxial layer, and further decreases the defects from the process.

The method for forming the recess includes a plurality of steps:

step 1: providing a silicon substrate, performing a first etching in a selected region of the silicon substrate to form a recess, wherein the first etching is a dry etching, and wherein the recess has either a U-shape or a ball-shape; and

step 2: placing the silicon substrate in an epitaxial process chamber, and performing a second etching to the recess by introducing reaction gases comprising HCl and GeH₄ in the epitaxial process chamber to form the recess into a diamond-shape.

In some cases, in step 1, a top surface of the silicon substrate is a surface (100); in step 2, etching rates of the second etching to a surface (110), the surface (100) and a surface (111) decrease sequentially.

In some cases in the second etching, a volume ratio of GeH₄ to HCl is a range of 0.1:1 to 1:1.

In some cases a temperature range of the second etching is 700° C.-800° C.

In some cases H₂ gas is used as a carrier gas in the second etching.

In some cases in step 1, the selected region of the silicon substrate is source and drain forming area at two sides of a gate structure.

In some example, the gate structure comprises a gate dielectric layer and a polysilicon gate, wherein the gate dielectric layer comprises silicon oxide, and wherein step 1 further comprises forming the gate structure on a top surface of the silicon substrate.

In some example, the gate structure comprises a gate dielectric layer and a metal gate, wherein the gate dielectric layer comprises a high-dielectric-constant material; wherein step 1 further comprises forming a pseudo gate structure in a forming region of the gate structure on the top surface of the silicon substrate, wherein the pseudo gate structure comprises a pseudo gate dielectric layer and a pseudo polysilicon gate, and wherein the pseudo gate structure is replaced by the gate structure in a subsequent process.

The disclosure further includes a method for forming a recess and filling the recess with an epitaxial layer in situ, which comprise a plurality of steps:

step 1: step 1: providing a silicon substrate, performing a first etching in a selected region of the silicon substrate to form a recess, wherein the first etching is a dry etching, and wherein the recess has either a U-shape or a ball-shape;

step 2: placing the silicon substrate in an epitaxial process chamber, and performing a second etching to the recess by introducing reaction gases comprising HCl and GeH₄ in the epitaxial process chamber to form the recess into a diamond-shape; and

step 3: performing an epitaxial growth process in situ in the epitaxial process chamber to fill the recess with an epitaxial layer.

In some examples, in step 1, a top surface of the silicon substrate is a surface (100), and in step 2, etching rates of the second etching to a surface (110), the surface (100) and a surface (111) decrease sequentially.

In some examples, in the second etching, a volume ratio of GeH₄ to HCl is in a range of 0.1:1 to 1:1.

In some examples, a temperature range of the second etching is 700° C.-800° C.

In some examples, H₂ gas is used as a carrier gas in the second etching.

In some examples, in step 1, the selected region of the silicon substrate is source and drain forming area at two sides of a gate structure.

In some examples, the gate structure comprises a gate dielectric layer and a polysilicon gate, wherein the gate dielectric layer comprises silicon oxide, and wherein step 1 further comprises forming the gate structure on a top surface of the silicon substrate.

In some examples, the gate structure comprises a gate dielectric layer and a metal gate, wherein the gate dielectric layer comprises a high-dielectric-constant material; wherein step 1 further comprises forming a pseudo gate structure in a forming region of the gate structure on the top surface of the silicon substrate, and wherein the pseudo gate structure comprises a pseudo gate dielectric layer and a pseudo polysilicon gate, and wherein the pseudo gate structure is replaced by the gate structure in a subsequent process.

In some examples, the epitaxial layer formed in step 3 comprises silicon germanium.

In some examples, the epitaxial layer formed in step 3 comprises silicon germanium.

Since the diamond-shaped recess is formed by performing further etching directly in the epitaxial process chamber in the present application, it is conducive to realizing the etching and epitaxial filling process of the recess in situ, thereby reducing steps in the process loop of forming embedded epitaxial layer finally, thus increasing the defects from the process.

### BRIEF DESCRIPTION OF THE DRAWINGS

The present application will be further described below in detail in combination with the embodiments with reference to the drawings.

FIGS. 1A-1D are cross sectional views of a gate structure following each step of an existing method in forming a recess and filling it with an epitaxial layer.

FIG. 2 is a flowchart of a method for forming a recess in a gate structure according to one embodiment of the present application.

FIGS. 3A-3C are cross sectional views of a gate structure following each step of a method in forming a recess according to one embodiment of the present application.

FIG. 4 is a cross sectional view of the gate structure after filling of an epitaxial layer into the recess in situ is completed according to one embodiment of the present application.

FIGS. 5A-5C depict with the molecular model each sub-step of the chemical reaction in the second wet etch in step 2 of the method above according to one embodiment of the present application.

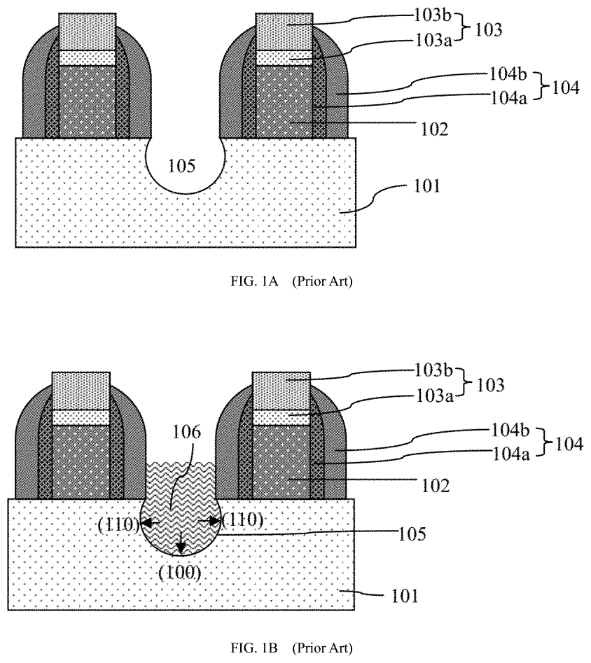

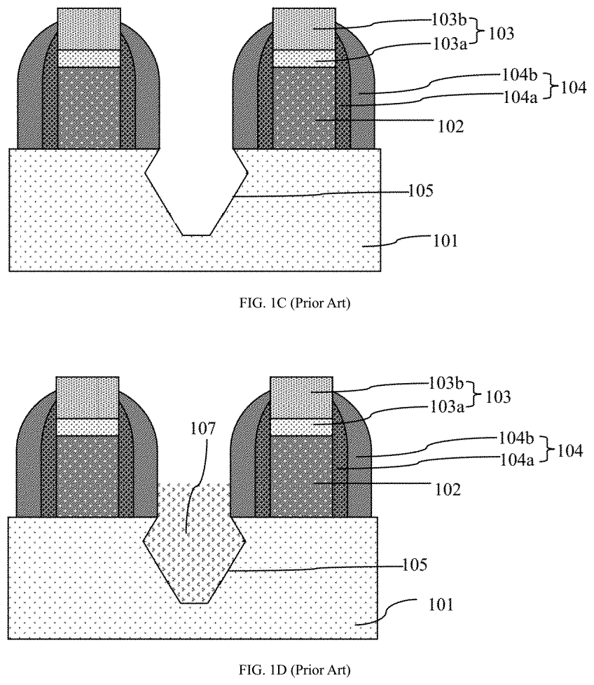

### DETAILED DESCRIPTION OF THE APPLICATION

Various embodiments of the present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “exemplary” are used to be examples with no indication of quality level. And terms are used both in the singular and plural forms interchangeably. Like numbers refer to like elements throughout.

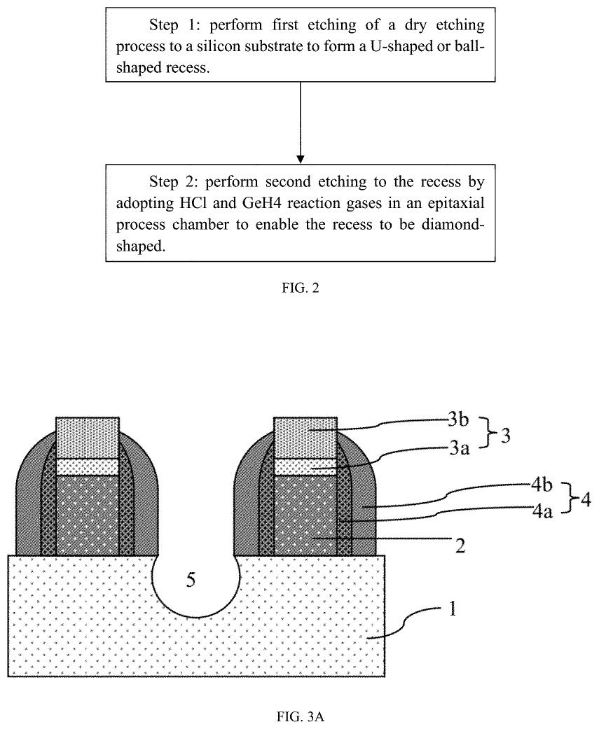

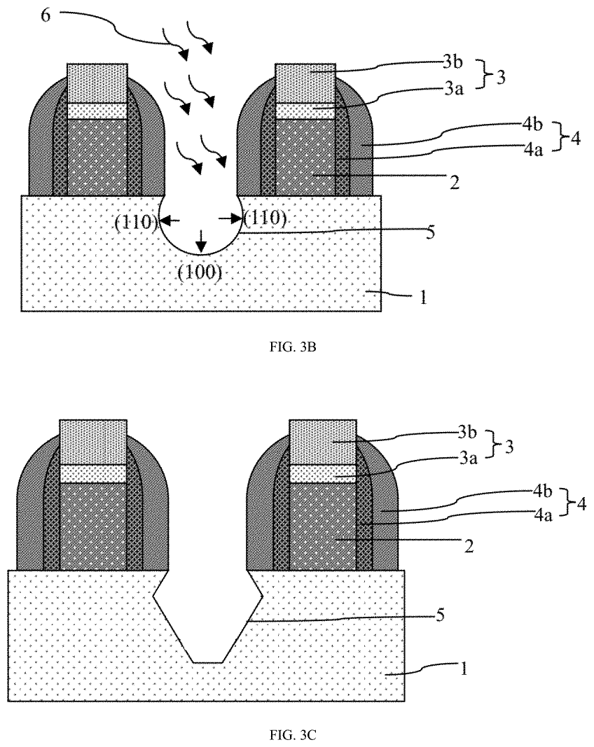

Referring to FIG. 2, it is a flowchart of a method for forming a recess in a gate structure according to one embodiment of the present application. FIGS. 3A-3C are cross sectional views of a gate structure following each step of a method in forming a recess according to one embodiment of the present application. The method includes the following steps:

In step 1, referring to FIG. 3A, first etching is performed, the first etching forms a recess 5 in a selected region of a silicon substrate 1, and the first etching enables the recess 5 to be U-shaped or ball-shaped by adopting dry etching. FIG. 3A illustrates that the recess 5 is ball-shaped, where part of the cross section is circular; alternatively the recess 5 may be U-shaped.

In the method according to one embodiment of the present application, a top surface of the silicon substrate 1 is the crystal surface (100).

The selected region of the recess 5 is source and drain forming regions on the two sides of a gate structure.

The gate structure is a superposed layer of a gate dielectric layer and a metal gate. The gate dielectric layer includes a high-dielectric-constant K layer. In step 1, a pseudo gate structure is formed on the top surface of the silicon substrate 1, the pseudo gate structure is formed in a forming region of the gate structure, and the pseudo gate structure is formed by superposing a pseudo gate dielectric layer (not shown) and a pseudo polysilicon gate 2; the pseudo gate structure is replaced by the gate structure in a subsequent process.

From FIG. 3A, a hard mask layer 3 is further formed on the top of the pseudo polysilicon gate 2, and sidewalls 4 are formed on the side surfaces of the pseudo gate structure. The hard mask layer 3 is formed by superposing a nitride layer 3b and an oxide layer 3b. The sidewalls 4 are formed by superposing oxide layer sidewalls 4a and nitride layer sidewalls 4b.

Alternatively, in other embodiments, the gate structure is a combination structure of a gate dielectric layer and a polysilicon gate, and the gate dielectric layer is composed of silicon oxide; in this case, in step 1, the gate structure is formed on the top surface of the silicon substrate 1, that is, the pseudo gate structure is not included but the gate structure is directly formed on the surface of the silicon substrate 1.

In step 2, referring to FIG. 3B, the silicon substrate 1 is placed in an epitaxial process chamber, and second etching is performed to the recess 5 by introducing hydrogen chloride (HCl) and Germane (GeH₄) reaction gases in the epitaxial process chamber. The second etching etchant is illustrated with wavy arrows represented by reference number 6.

Referring to FIG. 3C, the second etching enables the recess 5 to be diamond-shaped.

In the method according to this embodiment, in step 2, the etching rates of the second etching to the silicon crystal surface (110), surface (100) and surface (111) decrease sequentially. In FIG. 3B, straight arrows are used to show the etching directions on the surface (110) and the surface (100). The arrow corresponding to the etching direction on the surface (100) faces downward, and the arrow corresponding to the etching direction of the surface (110) faces to the left and the right sides.

In the second etching, the volume ratio of GeH₄ to HCl is in the range of 0.1:1 to 1:1.

The temperature range of the second etching is 700° C.-800° C.

H₂ is used as a carrier gas in the second etching.

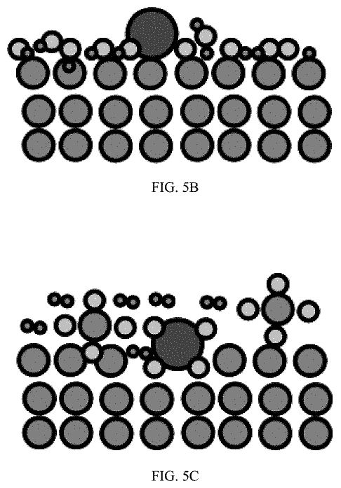

FIGS. 5A-5C depict with the molecular model each sub-step of the chemical reaction in the second wet etch in step 2 of the method according to one embodiment of the present application. The implementation process and principle of the second etching will be described below in combination with FIGS. 5A-5C and the following equations.

First, GeH₄ and HCl are provided. In FIG. 5A, silicon atoms are represented by reference 201, Ge atoms are represented by reference 202 (the atoms' sizes here are not in proportion), Cl atoms are represented by reference 203, and H atoms are represented by reference 204; the silicon substrate 1 is represented by silicon atoms 201 stacked together, GeH₄ consists of one Ge atom 202 and four H atoms 204, and HCl consists of one Cl atom 203 and one H atom 204.

Referring to FIG. 5B, GeH₄ is decomposed into Ge and H₂ gas at high temperature in the chamber, at 700° C.-800° C. for example; the corresponding chemical reaction equation is:

GeH₄=Ge+2 H₂

Thereafter, as in FIGS. 5B-5C, HCl reacts with Ge to produce GeCl₄ and 2 Hz; the corresponding chemical reaction equation is as follows:

4 HCl+Ge=GeCl₄+2 H₂

Thereafter, in FIG. 5C, surface silicon atoms react with the adsorbed GeCl₄ to produce SiCl₄ and Ge; the corresponding chemical reaction equation is as follows:

Si+GeCl₄=SiCl₄+Ge

Under the influence of high temperature and air flow, SiCl₄ is carried away, thus Si is etched.

In the second etching, the produced Ge plays the role of a catalyst, which accelerates the etching rate of surface Si.

Different from the existing method for forming the diamond-shaped recess 5, the present application does not use TMAH to perform wet etching to the recess 5 after forming the U-shaped or ball-shaped recess 5, instead it introduses HCl and GeH₄ reaction gases in the epitaxial process chamber to perform second etching to the recess 5. HCl and GeH₄ can also realize the selective etching of the crystal surface of the silicon substrate 1, so as to form the diamond-shaped recess 5.

Since the diamond-shaped recess 5 is formed by performing further etching directly in the epitaxial process chamber in the method according to one embodiment of the present application, it is conducive to realizing the etching and epitaxial filling process of the recess 5 in situ, thereby reducing the process steps in the process loop of the embedded epitaxial layer finally, and thus reducing the defects caused by the process steps.

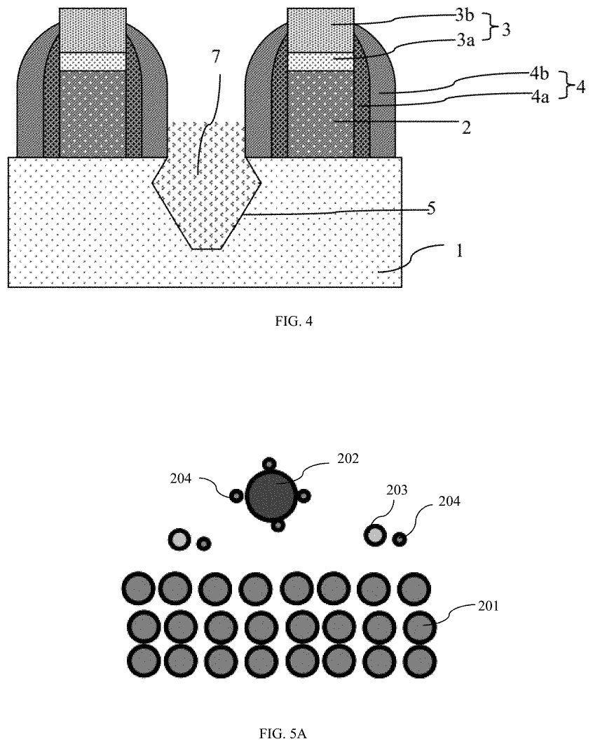

In the method for forming the recess and filling the epitaxial layer in situ according to one embodiment of the present application, based on one embodiment for forming the recess, after the recess is formed, a process of filling the recess with an epitaxial layer is performed in situ in the epitaxial process chamber. The steps of forming the recess are disclosed above and in FIGS. 3A-3C. FIG. 4 is cross sectional view of the gate structure after filling of an epitaxial layer into the recess in situ is completed according to one embodiment of the present application. The method for forming the recess and filling the epitaxial layer in situ according to one embodiment of the present application includes the following steps:

In step 1, referring to FIG. 3A, first etching is performed, the first etching forms a recess 5 in a selected region of a silicon substrate 1, and the first etching enables the recess 5 to be U-shaped or ball-shaped by adopting dry etching. FIG. 3A illustrates that the recess 5 is ball-shaped, that is, the cross section is a partial circle; alternatively the recess 5 may be U-shaped.

In the method according to one embodiment of the present application, a top surface of the silicon substrate 1 is a surface (100).

The selected region of the recess 5 is source and drain forming regions on the two sides of a gate structure.

The gate structure is a combination structure of a gate dielectric layer and a metal gate, and the gate dielectric layer includes a high-dielectric-constant K material; in step 1, a pseudo gate structure is formed on the top surface of the silicon substrate 1, the pseudo gate structure is formed in a forming region of the gate structure, and the pseudo gate structure is formed by superposing a pseudo gate dielectric layer and a pseudo polysilicon gate 2; the pseudo gate structure is replaced by the gate structure in a subsequent process.

From FIG. 3A, it can be seen that a hard mask layer 3 is further formed on the top of the pseudo polysilicon gate 2, and sidewalls 4 are formed on the side surfaces of the pseudo gate structure. The hard mask layer 3 is formed by superposing a nitride layer 3b and an oxide layer 3b. The sidewalls 4 are formed by superposing oxide layer sidewalls 4a and nitride layer sidewalls 4b.

Alternatively, in other embodiments, the gate structure is a combination structure of a gate dielectric layer and a polysilicon gate, and the gate dielectric layer consists of silicon oxide; in this case, in step 1, the gate structure is formed on the top surface of the silicon substrate 1, that is, the pseudo gate structure is not formed, instead the gate structure is directly formed on the surface of the silicon substrate 1.

In step 2, referring to FIG. 3B, the silicon substrate 1 is placed in an epitaxial process chamber, and second etching is performed to the recess 5 by adopting HCl and GeH₄ reaction gases in the epitaxial process chamber. The second etching is as illustrated by wavy arrows corresponding to reference 6.

Referring to FIG. 3C, the second etching enables the recess 5 to be diamond-shaped.

In the method according to one embodiment of the present application, in step 2, the etching rates in the second etching process to surface (110), surface (100) and surface (111) of crystalline silicon decrease sequentially. In FIG. 3B, straight arrows are used to show the etching directions of the surface (110) and the surface (100). It can be seen that the arrow corresponding to the etching direction of the surface (100) faces downward, and the arrow corresponding to the etching direction of the surface (110) faces to the left and right sides.

In the second etching, the volume ratio of GeH₄ to HCl is in the range of 0.1:1 to 1:1.

The temperature range of the second etching is 700° C.-800° C.

H₂ is used as a carrier gas in the second etching.

FIGS. 5A-5C depict each sub-step of the chemical reaction in the second wet etch in step 2 with the molecular model. The implementation process and principle of the second etching will be described below in combination with FIGS. 5A-5C and chemical reaction equations.

First, GeH₄ and HCl are provided. In FIG. 5A, silicon atoms are represented by reference 201, Ge atoms are represented by reference 202, Cl atoms are represented by reference 203, and H atoms are represented by reference 204; the silicon substrate 1 is represented by silicon atoms 201 stacked together, GeH₄ is represented by one Ge atom 202 and four H atoms 204, and HCl is represented by one Cl atom 204 and one H atom 204.

Referring to FIG. 5B, GeH₄ is decomposed into Ge and H₂ at high temperature, in the range of 700° C.-800° C.; the corresponding chemical reaction equation is as follows:

GeH₄=Ge+2 H₂

Thereafter, as in FIGS. 5B-5C, HCl reacts with Ge to produce GeCl₄ and H₂; the corresponding chemical reaction equation is as follows:

4 HCl+Ge=GeCl₄+2 H₂

Thereafter, in FIG. 5C, surface Si reacts with the adsorbed GeCl₄ to produce SiCl₄ and Ge; the corresponding chemical reaction equation is as follows:

Si+GeCl₄=SiCl₄+Ge

Under the influence of high temperature and air flow, SiCl₄ is removed away, thus Si etching is performed.

In the second etching, the produced Ge plays a role of a catalyst, which accelerates the etching rate of surface Si.

In step 3, an epitaxial growth process is performed in situ in the epitaxial process chamber to form an epitaxial layer 7 to completely fill the recess 5, shown in FIG. 4. In the method according to one embodiment of the present application, the formed epitaxial layer 7 includes a silicon germanium epitaxial layer.

The present application has been described above in detail through the specific embodiments, which, however, do not constitute limitations to the present application. Without departing from the principle of the present application, those skilled in the art may make many modifications and improvements, which should also be regarded as included in the scope of protection of the present application.

1. A method for forming a recess in a semiconductor device, comprising a plurality of steps:
step 1: providing a silicon substrate, performing a first etching in a selected region of the silicon substrate to form a recess, wherein the first etching is a dry etching, and wherein the recess has either a U-shape or a ball-shape; and
step 2: placing the silicon substrate in an epitaxial process chamber, and performing a second etching to the recess by introducing reaction gases comprising HCl and GeH₄ in the epitaxial process chamber to form the recess into a diamond-shape;
wherein in step 1, a top surface of the silicon substrate is a surface of crystal (100);
wherein in step 2, etching rates of the second etching to a surface of crystal (110), the surface of crystal (100) and a surface of crystal (111) decrease sequentially;
wherein step 1 further comprises forming a gate structure on a top surface of the silicon substrate;
wherein in step 1, the selected region of the silicon substrate is source and drain forming area at two sides of the gate structure;
wherein the gate structure comprises a gate dielectric layer and a polysilicon gate, wherein the gate dielectric layer comprises silicon oxide;
wherein the gate structure further comprises a metal gate, wherein the gate dielectric layer comprises a high-dielectric-constant material;
wherein step 1 further comprises forming a pseudo gate structure in a forming region of the gate structure on the top surface of the silicon substrate, wherein the pseudo gate structure comprises a pseudo gate dielectric layer and a pseudo polysilicon gate; and
wherein the pseudo gate structure is replaced by the gate structure in a subsequent process.

2. (canceled)

3. The method for forming the recess according to claim 1, wherein in the second etching, a volume ratio of GeH₄ to HCl is a range of 0.1:1 to 1:1.

4. The method for forming the recess according to claim 3, wherein a temperature range of the second etching is 700° C.-800° C.

5. The method for forming the recess according to claim 3, wherein H₂ gas is used as a carrier gas in the second etching.

6-8. (canceled)

9. A method for forming a recess and filling the recess with an epitaxial layer in situ comprising a plurality of steps:
step 1: providing a silicon substrate, performing a first etching in a selected region of the silicon substrate to form a recess, wherein the first etching is a dry etching, and wherein the recess has either a U-shape or a ball-shape;
step 2: placing the silicon substrate in an epitaxial process chamber, and performing a second etching to the recess by introducing reaction gases comprising HCl and GeH₄ in the epitaxial process chamber to form the recess into a diamond-shape; and
step 3: performing an epitaxial growth process in situ in the epitaxial process chamber to fill the recess with an epitaxial layer;
wherein in the step 1, the selected region of the silicon substrate is source and drain forming area at two sides of a gate structure;
wherein the gate structure comprises a gate dielectric layer and a polysilicon gate, wherein the gate dielectric layer comprises silicon oxide, and wherein step 1 further comprises forming the gate structure on a top surface of the silicon substrate;
wherein the gate structure further comprises a gate dielectric layer and a metal gate, wherein the gate dielectric layer comprises a high-dielectric-constant material;
wherein the step 1 further comprises forming a pseudo gate structure in a forming region of the gate structure on the top surface of the silicon substrate, and wherein the pseudo gate structure comprises a pseudo gate dielectric layer and a pseudo polysilicon gate; and
wherein the pseudo gate structure is replaced by the gate structure in a subsequent process.

10. (canceled)

11. The method for forming the recess and filling the recess with the epitaxial layer in situ according to claim 9, wherein in the second etching, a volume ratio of GeH₄ to HCl is in a range of 0.1:1 to 1:1.

12. The method for forming the recess and filling the recess with the epitaxial layer in situ according to claim 11, wherein a temperature range of the second etching is 700° C.-800° C.

13. The method for forming the recess and filling the recess with the epitaxial layer in situ according to claim 11, wherein H₂ gas is used as a carrier gas in the second etching.

14-16. (canceled)

17. The method for forming the recess and filling the recess with the epitaxial layer in situ according to claim 9, wherein the epitaxial layer formed in step 3 comprises silicon germanium.

18. (canceled)
